(19) United States
(12) Patent Application Publication
(10) Pub. No.: US 2003/0110438 A1
(43) Pub. Date: Jun. 12, 2003

(54) Turbo decoder, and a MAP decoder component of the turbo decoder

(76) Inventors: Ju Yan Pan, Singapore (SG); Hiroshi Katsuragawa, Singapore (SG); Noriyoshi Ito, Tokyo (JP)

Correspondence Address: VENABLE, BAETJER, HOWARD AND CIVILETTI, LLP, P.O. BOX 34385, WASHINGTON, DC, 20043-9998, US

(21) Appl. No.: 10/193,145

(22) Filed: Jul. 12, 2002

(30) Foreign Application Priority Data
Dec. 7, 2001 (SG) 200107761-9

(51) Int. Cl. H03M 13/00

(52) U.S. Cl. 714/755; 714/786

(57) ABSTRACT

A MAP decoder for decoding turbo codes obtains λ-values for a series of symbols (e.g. a block of symbols or a window within a block) using a two-stage process. The series of symbols is partitioned into two sequences, which are processed in parallel. In a first phase, α-values are worked out for a first of the sequences and the β-values for the second sequence. Then, in the second phase, simultaneously (i) the β-values for the first sequence are found, and used with the memorised α-values to find the λ-values for the first sequences, and (ii) the α-values for the second sequence are found, and used with the memorised β-values for that sequence, to find the λ-values for the second sequence. We also propose a turbo decoder including at least one such MAP decoder.

### FIELD OF THE INVENTION

The present invention relates to new methods of performing MAP decoding, to MAP decoders employing the methods, and to turbo decoders including the MAP decoders.

### BACKGROUND OF THE INVENTION

“Turbo codes” are used as a technique of error correction in practical digital communications. The essence of the decoding technique of turbo codes is to produce soft decision outputs, i.e. different numerical values which describe the different reliability levels of the decoded symbols, which can be fed back to the start of the decoding process to improve the reliabilities of the symbols. This is known as an iterative decoding technique. Turbo decoding has been shown to perform close to the theoretical limit (Shannon limit) of error correction performance after 18 iterations (C. Berrou, A. Glavieux, and P. Thitimajshima, “Near Shannon Limit Error-Correcting Coding and Decoding: Turbo-Codes (1)”, Proc. IEEE ICC, Geneva, Switzerland, 1993, pp. 1064-1070, the disclosure of which is incorporated herein by reference in its entirety).

The turbo decoding algorithm is a very complex and it takes up a large amount of computation time and consumes a lot of memory resources. Specifically, this algorithm is performed by a component called the MAP (maximum a posteriori) decoder, running an algorithm which derives quantities which are the internal signals α, β and λ.

In general, the turbo encoder (“or turbo codes”), shown schematically in FIG. 1, is a pair of parallel concatenated convolutional encoders 12, 13 separated by an interleaver 11. It accepts an input binary {0,1} sequence of a specified code block of size N symbols, and produces three types of encoded output for each symbol. The three types of output are shown as x, y, z respectively.

The turbo decoder, shown schematically in FIG. 2, receives the encoded signals and uses all three types of signals to reproduce the original bit sequence of the turbo encoder input. Two MAP decoders 21 and 24, associated with the convolutional encoders 12 and 13 respectively, perform the decoding calculations. The turbo decoder also includes an interleaver 22 to mirror the interleaver 11 of the encoding side, and a deinterleaver 23 to reconstruct the correct arrangement of the bit sequence to be fed back from decoder 24 to decoder 21. The decoded bits after the final iteration are hard decisions, i.e. output binary sequence {0,1}, obtained from decoder 24 (though depending on when the iteration stops, the final hard decisions may alternatively be obtained from decoder 21).

Each of the decoders 21, 23 uses the BCJR algorithm (L. R. Bahl, J. Cocke, F. Jelinek, and J. Raviv, “Optimal Decoding of Linear Codes for Minimizing Symbol Error Rate”, IEEE Transactions on Information Theory, vol. IT-20, March 1974, pp. 284-287) to compute soft outputs, or likelihoods. Using the received signals x,y and z, the algorithm computes a quantity called the transitional probability γ for each symbol in the block (John G. Proakis, “Digital Communications”, 3^{rd} ed., p 378-379). γ is then used to compute three types of probabilities: α, β and λ. In turbo decoding, the computation of γ also takes into account the feedback information, also known as extrinsic information.

In a sense, a represents the likelihood probability of a symbol changing from a state m′ (e.g. one of the 2^{K} states, where K is the constraint length of the convolutional encoder) to another state m as the time interval progresses from t to t+1. The β probability, on the other hand, corresponds to the likelihood probability of a symbol changing from a state m to m′ from the time interval t to t-1. α and β are also known as forward and backward probabilities. The initial values for α and β are known because the states at the start and the end of the block N are set to zero in the turbo encoder. The joint probability λ fuses α and β together to obtain one measure of likelihood for each symbol. λ will then be used to compute the output of the turbo decoder which will be either the soft decisions (feedback) or the hard decisions ({0,1} bits).

These three probabilities must be computed sequentially, and normalized for each symbol. The computations of α, β and λ are briefly described in the equations below:

$$\begin{matrix}{α}_{t} ( m ) = {\sum }_{{m}^{′}} {α}_{t - 1} ( {m}^{′} ) \cdot {Y}_{t} ( {m}^{′} , m ) & ( 1 ) \\ {β}_{t} ( m ) = {\sum }_{{m}^{′}} {β}_{t + 1} ( {m}^{′} ) \cdot {Y}_{t + 1} ( m , {m}^{′} ) & ( 2 ) \\ {λ}_{t} ( m ) = {\sum }_{{m}^{′}} {α}_{t} ( {m}^{′} ) \cdot {Y}_{t} ( {m}^{′} , m ) \cdot {β}_{t + 1} ( m ) & ( 3 )\end{matrix}$$

As can be seen, α and β are independent of each other, but λ is dependent on α and β. A complete algorithm requires that the α and β probabilities for all symbols N are used to calculate λ. This could take up much memory storage and processing time for the calculations.

There are various implementations of MAP decoders which help ease these problems:

Sliding-window—the N symbols are divided into portions of size N_{w} symbols and calculations are performed on the each small block as if it were a complete block by itself; however, the calculations of α and β must be given a head start of L symbols (L could be as small as 16 bits) to estimate reliable initial probabilities as the α and β calculation processes no longer begin from the start and end of the block N.

Log-MAP approximation—calculations are performed in log domain for simplicity and stability. That is, variants of equations (1)-(3) are used, as described in P. Robertson, P. Hoeher, E. Villebrun, “Optimal and Sub-Optimal Maximum a Posteriori Algorithms Suitable for Turbo Decoding”.

Max-log-MAP approximation—a simplified version of the log-MAP, again with variants of equations (1)-(3), and again as discussed in Robertson et al.

The most straightforward way is to implement the computations, as illustrated in FIG. 3, uses two memory buffers 34, 35 and three processors 32, 33, 36 in between the source buffer 31 and the output buffer 37. The source 31 stores the received signals and extrinsic symbols to calculate γ, which is needed in the computation of all three α, β and λ probabilities. The computation of α, β (32 and 33) for all N symbols can be done simultaneously and stored in two memory buffers 34 and 35. Note that the computation of α and β for symbols 1 and N is trivial (and does not require a calculation) since the message for symbols 1 and N is known. The λ processor 36, which needs α and β information before it can begin calculation, is the last stage of computation before all λ values for all symbols N are deposited into 37. FIG. 4 provides a clearer picture of the timeline for the implementation illustrated in FIG. 3.

Explanation of the implementation sequence from the timing diagram in FIG. 4:

At time t₁

start to compute α from symbols 1 to N

start to compute β from symbols N to 1

At time t₂

end of beta computation: β for 1^{st} symbol is computed

end of alpha computation: α for N^{th} symbol is computed

start to compute A from symbols 1 to N

At time t₃

end of lambda computation: λ for N^{th} symbol is computed

Another way of implementation which requires less memory storage requirement but longer processing time is illustrated in FIG. 5. The β calculator 52 obtains the relevant information from source 51 and starts the computation first. After the β values for all N symbols have been computed and stored in memory 53, the a calculator 54 and the corresponding λ calculator 55 can begin the final lap of calculations for N symbols of λ to be stored in 56. FIG. 6 illustrates the timeline of this implementation.

Explanation of the implementation sequence from the timing diagram in FIG. 6:

At time t₁

start to compute β from symbols N to 1

At time t₂

start to compute a from symbols 1 to N

start to compute A from symbols 1 to N

end of beta computation: β for 1^{st} symbol is computed

At time t₃

end of alpha computation: α for N^{th} symbol is computed

end of lambda computation: λ for N^{th} symbol is computed

As mentioned previously, the biggest issue of turbo decoder implementation is the huge complexity which hinders the management of memory storage and processing speed. Recently, as turbo coding is applied to real systems, we need to employ very fast turbo decoding while keeping the buffer storage requirement as small as possible. The previous arts can succeed in either increasing the speed by realizing parallel computation or reducing the memory requirement by careful arrangement of buffers and processors, but not both.

### SUMMARY OF THE INVENTION

The present invention seeks to provide new and useful methods and devices for performing MAP decoding, and turbo encoders incorporating the devices.

In particular, the present invention makes it possible to achieve a faster processing speed while maintaining a small memory requirement compared with the two prior art systems described in the previous section.

In general terms, the present invention proposes that α- and β-values for a series of symbols (e.g. a block of symbols or a window within a block) are obtained in a two-stage process. The series of symbols is partitioned into two sequences, which are processed in parallel. In a first phase, the α-values are computed for a first of the sequences and the β-values for the second sequence. Then, in the second phase, simultaneously (i) the β-values for the first sequence are found, and used with the memorised α-values to find the β-values for the first sequences, and (ii) the α-values for the second sequence are found, and used with the memorised β-values for that sequence, to find the λ-values for the second sequence.

Thus, the method can be performed using one processor for finding α-values, one for finding β-values and one for finding λ-values.

To appreciate the time and memory requirements achievable using the invention, consider initially the case in which the series of symbols is a full implementation (block) of size N (rather than a sliding window of size N_{w}). In this case, labelling the series of symbols t=1, . . . , N, the values of α and β are known for symbols t=1 and t=N, so that the problem reduces to calculating their values for t=2 to t=N−1, and the λ-values for t=1 to t=N. In this case it is preferable that the first sequence consists of the symbols t=1 to t=N/2, and the second sequence consists of the symbols t=N/2+1 to t=N.

In this case, the first phase results in a total of N α- and β-values to be memorised (including the values for t=1 and t=N), but these coefficients can be discarded successively as the N λ-values are successively found in the second phase. Thus, the memory requirement in embodiments of the invention may be only a total of N values.

Similarly, the time taken by each of the phases is a function of N/2, rather than N. Specifically, the time taken by the first phase is the time taken to calculate the α- and β-values for each of the sequences (i.e. if each sequence consists of N/2 symbols, the first phase may be N/2 times the time taken to calculate one α- or β-value), and the time taken by the second phase is likewise N/2 times the time taken to find the remaining α- or β-value plus the λ-value for one symbol.

However, the present invention is not limited to the case in which the series of symbols includes an entire block, and it is also applicable to cases in which the series of symbols is a window of N_{w} symbols within a block (e.g. of length N), so that the values of α and β are not initially known for symbols t=1 and t=N_{w}.

In this case (but not only in this case), the first sequence may selected to begin at a value of which is greater than 1, and we define a third sequence of L symbols (e.g. for L=16) prior to the first sequence (and running up to the beginning of the first sequence). The first phase then includes working out approximation α-values for the third sequence, to derive a good estimate of the α-value for the first symbol of the first sequence. The approximation values are not normally used during the second phase. Similarly, the second sequence may be selected to extend only up to a symbol which is earlier within the series than N_{w}, and we define a fourth sequence of symbols (e.g. also L in length) directly following the second sequence. The first phase then includes working out approximation β-values for the fourth sequence, to derive a good estimate of the β-value for the final symbol of the second sequence. The approximation α and β-values are not normally used during the second phase.

In presently preferred embodiments of the invention, the calculations of all α-, β- and λ-values are performed using equations (1) to (3) as in known systems. But embodiments of the present invention can be constructed for variants this decoding method (i.e. defined by variants of equations (1) to (3)), such as may be proposed or adopted in the future.

Specifically, in a first expression the present invention provides a method of decoding an message which is a series of symbols labelled by integer variable t and encoded using a turbo-coder which for each symbol t takes a corresponding one of a set of M states m=0, . . . ,M, the method including obtaining:

for each said symbol t and state m, a primary probability value αₜ(m) representing, except for the first symbol, the probability of the symbol t being state m given the primary probability values at the preceding symbol,

for each said symbol t and state m, a secondary probability value βₜ(m) representing, except for the final symbol, the probability of the symbol t being state m given the secondary probability values at the succeeding symbol,

for each said symbol t and state m, a third value λₜ(m) derived from the primary and secondary probability values at that symbol,

characterized in that the method includes:

a first phase in which the primary probability values are derived for a first sequence of said symbols, and the secondary probability values are derived for a second sequence of said symbols; and

a second phase following the first phase in which in parallel for the two sequences:

(i) the secondary probability values for the first sequence are derived, and used with the primary probability values for the first sequence to derive the third values for the first sequence, and

(ii) the primary probability values for the second sequence are derived, and used with the secondary probability values for the second sequence to derive the third values for the second sequence.

An alternative expression of the invention is as a MAP decoder for decoding an message which is a series of symbols labelled by integer variable t and encoded using a turbo-coder which for each symbol t takes a corresponding one of a set of M states m=0, . . . ,M, the decoder including a processor arranged to obtain:

for each said symbol t and state m, a primary probability value αₜ(m) representing, except for the first symbol, the probability of the symbol t being state m given the primary probability values at the preceding symbol,

for each said symbol t and state m, a secondary probability value βₜ(m) representing, except for the final symbol, the probability of the symbol t being state m given the secondary probability values at the succeeding symbol,

for each said symbol t and state m, a third value λₜ(m) derived from the primary and secondary probability values at that symbol,

characterized in that the processor is arranged to operate in two phases consisting of:

a first phase in which the primary probability values are derived for a first sequence of said symbols, and the secondary probability values are derived for a second sequence of said symbols; and

a second phase following the first phase in which in parallel for the two sequences:

(i) the secondary probability values for the first sequence are derived, and used with the primary probability values for the first sequence to derive the third values for the first sequence, and

(ii) the primary probability values for the second sequence are derived, and used with the secondary probability values for the second sequence to derive the third values for the second sequence.

Note that the term “derive” is used in both definitions specifically to include the case in which, due to prior knowledge of the message, the primary and/or secondary probability values for certain values of t are derived without a calculation based on the encoded message (e.g. even before the message is received). For example, as discussed above in certain embodiments using such prior knowledge the primary probability values αₜ(m) may be (pre-)derived for all m for t=1, and the secondary probability values βₜ(m) may be (pre-)derived for all m for t=N.

The present invention further proposes a turbo decoder incorporating at least one unit of the above MAP decoder. For example, one or both of the units 21, 24 in a turbo decoder having the general form shown in FIG. 2 may be a MAP decoder according to the present invention.

### BRIEF DESCRIPTION OF THE FIGURES

A non-limiting embodiment of the invention will now be described for the sake of example only with reference to the figures in which:

FIG. 1 shows a known turbo encoder;

FIG. 2 shows a known turbo decoder,

FIG. 3 shows a known MAP decoder,

FIG. 4 shows a mode of operation of the decoder of FIG. 3,

FIG. 5 shows a known MAP decoder,

FIG. 6 shows a mode of operation of the decoder of FIG. 5,

FIG. 7 shows a MAP decoder which is an embodiment of the invention,

FIG. 8 shows a first mode of operation of the embodiment of FIG. 7, and

FIG. 9 shows a second mode of operation of the embodiment of FIG. 7.

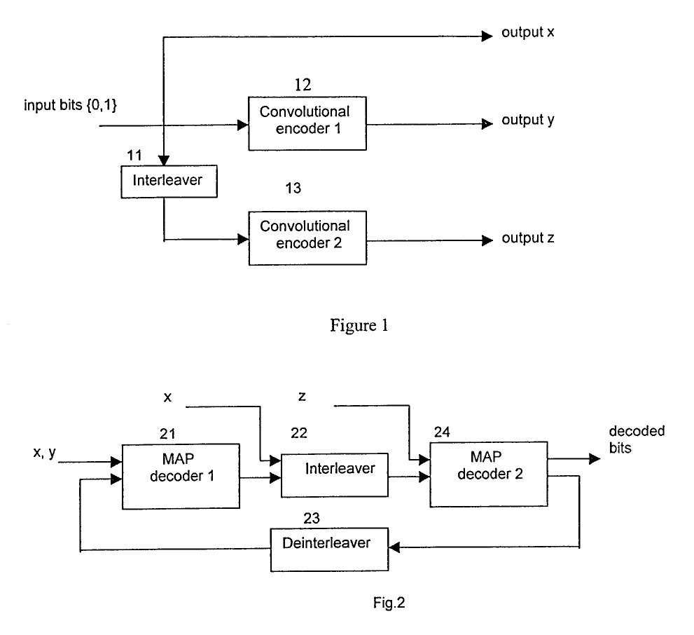

### DESCRIPTION OF THE EMBODIMENTS

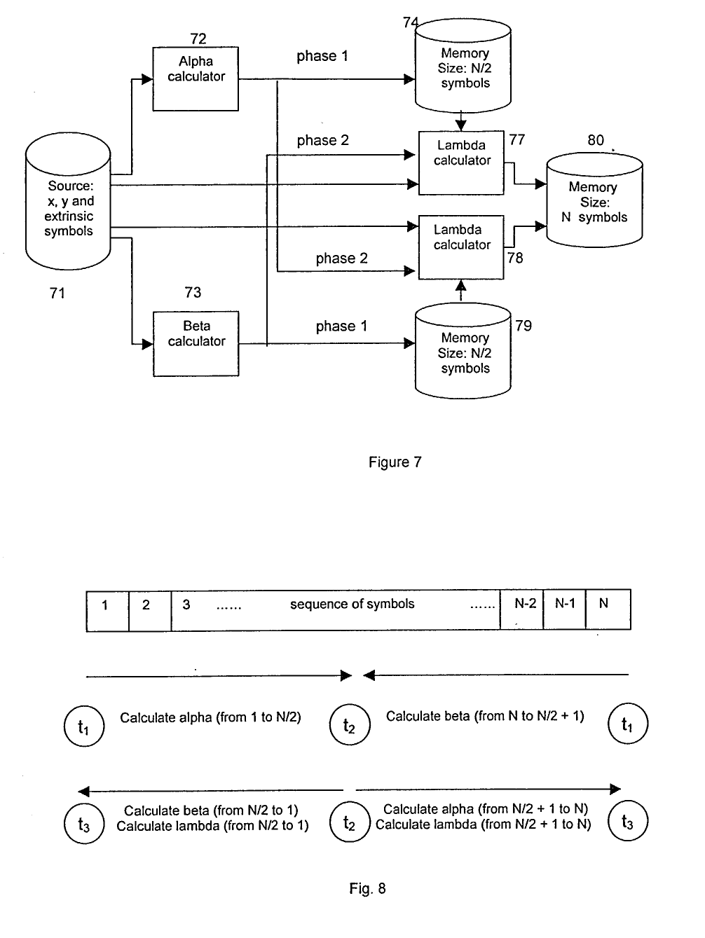

Turning to FIG. 7, a first embodiment of the invention is shown. To explain the operation of the embodiment, let us consider firstly a situation in which the embodiment of FIG. 7 is used to process a complete block of size N.

In a first phase, an α-value calculator 72 and β-value calculator 73 acquire relevant information from data source 71 to simultaneously begin their calculations from respective ends of the block. At the halfway point (when a for the N/2-th symbol and β for the (N/2+1)-th symbol have been calculated), the calculated α and β probabilities have occupied the memory storages 74 and 79 for a combined usage of N symbols memory storage.

In a second phase, the α calculator 72 and β calculator 73 continue the simultaneous computations, and λ calculators 77 and 78 begin computation using α and β values as they are calculated, together with the stored α and β values found in the first phase. Calculators 77 and 78 operate simultaneously. At the end of the all computations, N symbols of λ probabilities are stored in database 80.

FIG. 8 describes the timing sequence of the embodiment:

At time t₁ (start of the first phase)

calculator 72 starts to compute α from symbols 1 to N/2

calculator 73 starts to compute β from symbols N to N/2+1

At time t₂ (start of the second phase)

calculator 72 starts to compute α from symbols N/2+1 to N

calculator 73 starts to compute β from symbols N/2 to 1

calculator 77 starts to compute λ from symbols N/2+1 to N

calculator 78 starts to compute λ from symbols N/2 to 1

At time t₃

end of alpha computation: α for N^{th} symbol is computed

end of beta computation: β for 1^{st} symbol is computed

end of lambda computation: λ for 1^{st} and N^{th} symbols are computed

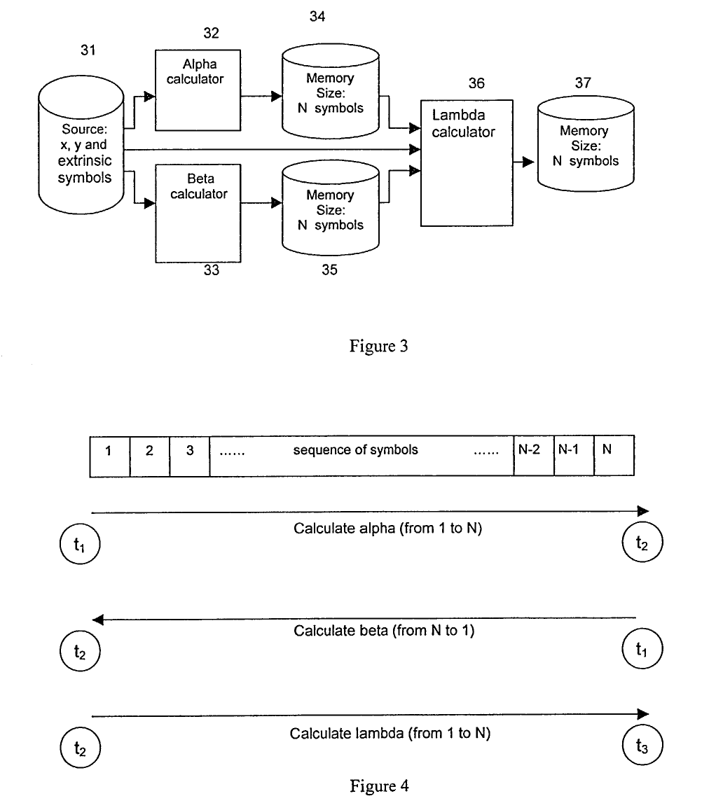

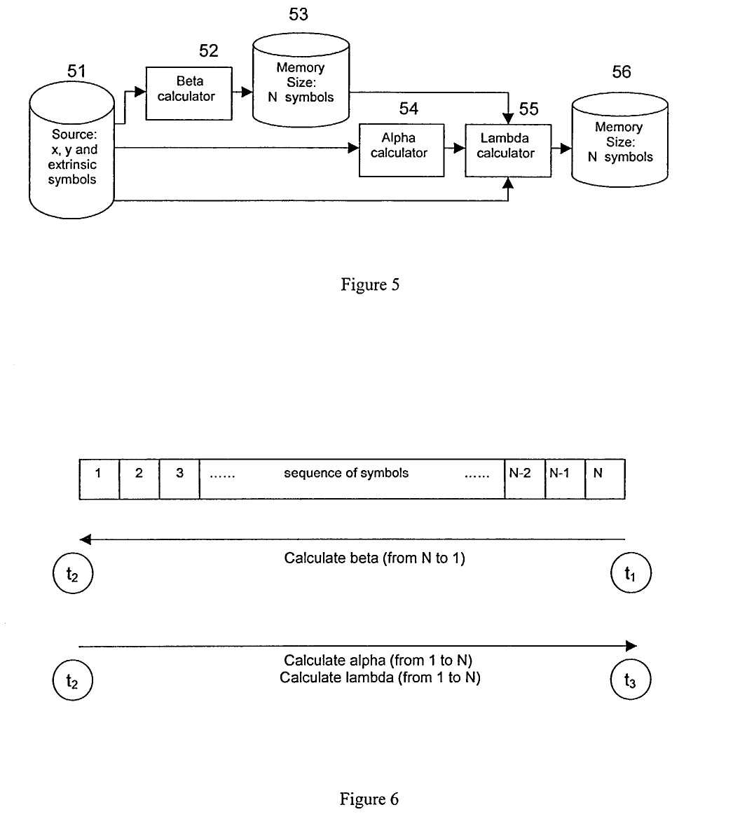

Table 1 provides a comparison among the different implementation in terms of memory requirement, processing speed and amount of processors.

| | | | Present | Present |
|---|---|---|---|---|
| | | | Embodiment, | Embodiment, with |
| | Prior art system | Prior Art System | with operation | operation shown in |
| | of FIG. 3 | of FIG. 5 | shown in FIG. 8 | |
| Memory | 2N | N | N | N |
| requirement | | | | |
| Processing | T_{αβ}(N) plus | T_{αβ}(N) plus the | T_{αβ}(N/2) plus | T_{αβ}(N/2+L) plus the |
| time | T_{λ}(N) | higher of T_{αβ}(N) | the higher of | higher of T_{αβ}(N/2) |
| | | and T_{λ}(N) | T_{αβ}(N/2) and | and T_{λ}(N/2) |
| | | | T_{λ}(N/2) | |
| Number of | 2P_{αβ}+P_{λ} | 2P_{αβ}+P_{λ} | 2P_{αβ}+2P_{λ} | 2P_{αβ}+2P_{λ} |
| processors | | | | |

In Table 1, “T_{αβ}(Z)” refers to the amount of time needed to compute α or β (assuming that the computations of α and β take the same amount of time) for Z symbols. T_{λ}(Z) refers to the amount of time needed to compute λ for Z symbols. Note that table 1 neglects the saving in time obtained due to the lack of necessity to calculate the values of α and β if the message at t=1 and/or t=N is known (since this saving does not scale with N). P_{αβ} refers to the number of calculators for calculating values of α or β (assuming that the construction of a α calculator 72 takes up the same amount of resources as a β calculator 74). P_{λ} refers to the number of calculators for calculating the values of λ.

It is seen that by using our proposed innovation of parallel computation, the processing speed can be improved, in fact halving the processing time required by a MAP processor to calculate λ values compared with the prior art systems of FIGS. 3 and 5. Our proposal also has the low memory storage requirement of the prior art system of FIG. 5.

Furthermore, the proposed implementation will not have any effect on the performance of the decoder because the numbers used in the calculations of the probabilities for all N symbols are exactly the same as the ones used in the prior art systems.

Whereas the mode operation shown in FIG. 8 is particularly suitable when the embodiment processes all N symbols of a block, a variation of this mode of operation is to start the α and β calculations from the centre instead of both ends of the series of symbols. This variation is particularly, but not exclusively, suitable to a case in which the series of symbols is not a complete block, but only a window within a block. In this variation, the computations need a head start of L symbols before a reliable initial probability can be produced. The derived α- and β-values for these L symbols, however, can be successively discarded before the initial probability is obtained; therefore, there is no need to set up memory storage for the extra L values.

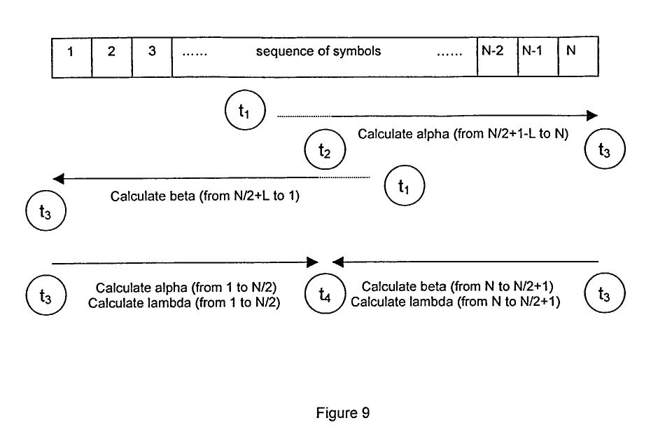

There are no differences in the hardware construction of this variation compared with FIG. 7. There are the same numbers of memory buffers and processors, and they are arranged in the same way. However, the calculators 72, 73. 77, 78 are programmed to operate with the timeline shown in FIG. 9.

Explanation of the implementation sequence from the timing diagram in FIG. 9:

At time t₁ (start of phase 1)

start to compute α from symbols N/2+1−L to N/2

start to compute β from symbols N/2+L to N/2+1

At time t₂

start to compute α from symbols N/2+1 to N

start to compute β from symbols N/2 to 1

At time t₃ (start of phase 2)

start to compute α from symbols 1 to N/2

start to compute β from symbols N to N/2+1

start to compute λ from symbols 1 to N/2

start to compute λ from symbols N to N/2+1

At time t₄

end of α computation: alpha for N^{th}/2 symbol is computed

end of β computation: beta for N^{th}/2+1 symbol is computed

end of λ computation: lambda for N^{th}/2 and N^{th}/2+1 symbols are computed

From Table 1, it can be seen that the improvements brought by the timeline of FIG. 9 is almost the same as that of FIG. 8. The only difference is the processing time of the α and β calculators is slightly increased because of the extra L symbols.

There should be some, although extremely negligible, degradation in the decoding performance compared with the first embodiment because an initialization build-up is needed to approximate the initial conditions. However, this variation is could be advantageous for sliding-window implementation because L symbols needed to calculate the initial conditions are obtained from their sliding-window block N_{w} instead of neighboring sliding-window blocks; this eases the processing implementations, especially those related to calculating the interleaving position.

We now consider variations on the modes of operation illustrated in FIGS. 8 and 9. Both of those modes of operation assume that the processing time for α and β computations are the same. However, now consider the possibility that they are not. In this case, we propose to vary the embodiment of FIG. 7 such that the buffers 74, 79 are of different sizes. The total memory requirement, however, remains the same: N symbols.

For example, consider how the mode of operation illustrated in FIG. 8 would be varied if we assume that the computation of α is twice as fast as that of β. Then the processing time in phase 1 (now defined in a generalised way as the perid until at least one of alpha and beta is found for each symbol) is T_{α}(2N/3) which is equal to T_{β}(N/3). This means that more α-values are computed in phase 1 than β-values, corresponding to a α:β buffer size ratio of 2:1. Specifically, at the end of phase 1 α is known for 2N/3 symbols and β is known for N/3 symbols. The time taken in phase 2 is then the higher of T_{β}(2N/3) and the time taken by the processor 77 (which has more work to do—i.e. 2N/3 λ-calculations—than the processor 78). In other words, the total time is T_{β}(N/3) plus the higher of T_{β}(2N/3) and T_{λ}(2N/3).

We can also consider how the mode of operation illustrated in FIG. 9 should be varied in that case that T_{α} is not equal to T_{β}. In this case, the first and second sequences advantageously do not start from the centre of the series of symbols. For example, writing T_{α}/T_{β} as a/b, we obtain that in order for the calculation of α in phase 1 to finish at the same time as the calculation of β (which minimises the time taken in phase 1), in phase 1 the values of α should be calculated from (N/2+1)a/b−L to N, and the values of β should be calculated from (N/2)a/b+L down to 1.

Although the present invention has been described above in relation to only a single embodiment, and its various possible modes of operation, many variations are possible within the scope of the invention.

In particular, the present invention proposes that the methods described above are implemented within at least one of the MAP units of a turbo decoder, as shown for example in FIG. 2. Currently, turbo codes are commonly applied as error correction codes in third-generation systems, which deal with high-speed data rate communications. Therefore, high-speed performance for turbo decoding is desirable. For instance, in the IMT-2000 specification, the turbo decoder is expected to perform at 2 Mbps-10 Mbps processing speed. Furthermore, a high data rate would also mean more memory requirement. Preferred embodiments of the present invention can combat these problems.

Furthermore, the present invention is not limited to decoding using equations (1) to (3); rather these can be varied as is well known in this field to vary the underlying decoding process without affecting the implementation advantages afforded by embodiments of the present invention.

Also, while it is preferable to preform decoding according to the present invention for all symbols of the message, sub-optimal embodiments are possible within the scope of the invention in which, for example, α-values are derived only for symbols from 1 to a value less than N, and β-values from N down to a value more than 1. All such variations in the underlying decoding algorithm can be implemented within the scope of the present invention.

1. A method of decoding an message which is a series of symbols labelled by integer variable t and encoded using a turbo-coder which for each symbol takes a corresponding one of a set of M states m=0, . . . ,M, the method including obtaining:
for each said symbol t and state m, a primary probability value αₜ(m) representing, except for the first symbol, the probability of the symbol t being state m given the primary probability values at the preceding symbol,
for each said symbol t and state m, a secondary probability value βₜ(m) representing, except for the final symbol, the probability of the symbol t being state m given the secondary probability values at the succeeding symbol,
for each said symbol t and state m, a third value λₜ(m) derived from the primary and secondary probability values at that symbol,
characterized in that the method includes:
a first phase in which the primary probability values are derived for a first sequence of said symbols, and the secondary probability values are derived for a second sequence of said symbols; and
a second phase following the first phase in which in parallel for the two sequences:
(i) the secondary probability values for the first sequence are derived, and used with the primary probability values for the first sequence to derive the third values for the first sequence, and
(ii) the primary probability values for the second sequence are derived, and used with the secondary probability values for the second sequence to derive the third values for the second sequence.

2. A method according to claim 1 in which the message consists of a block of N symbols (t=1, . . . ,N) and the message for symbols t=1 and t=N is initially known, whereby the values of α₁(m) and β_{N}(m) for all m are derived without a calculation based on the encoded message.

3. A method according to claim 2 in which each of the first and second sequences include N/2 said symbols.

4. A method according to claim 3 in which the first sequence begins at t=1, and the second sequence extends to t=N.

5. A method according to claim 1 in which the first phase of the method includes deriving approximation values of the primary and secondary probability values respectively in third and fourth sequences of said symbols, the third sequence preceding the first sequence and the fourth sequence following the second sequence,
said approximation values not being employed in the second phase to calculate the third quantity.

6. A method according to claim 5 in which the block consists of N_{w} symbols, the message for symbols t=1 and symbol t=N_{w} is not initially known, the first sequence extends up to t=N_{w} and the second sequence extends down to t=1.

7. A method according to claim 1 in which the primary probability value αₜ(m) and secondary probability value βₜ(m) are determined based on a transitional probability value λₜ(m, m′) which is derived from the encoded message and which represents the probability of transitions between states m and m′.

8. A method according to claim 1 further including using the third values λₜ(m) to make decisions identifying the symbols of the decoded message.

9. A MAP decoder for decoding an message which is a series of symbols labelled by integer variable t and encoded using a turbo-coder which for each symbol t takes a corresponding one of a set of M states m=0, . . . ,M, the decoder including a processor arranged to obtain:
for each said symbol t and state m, a primary probability value αₜ(m) representing, except for the first symbol, the probability of the symbol t being state m given the primary probability values at the preceding symbol,
for each said symbol t and state m, a secondary probability value βₜ(m) representing, except for the final symbol, the probability of the symbol t being state m given the secondary probability values at the succeeding symbol,
for each said symbol t and state m, a third value λₜ(m) derived from the primary and secondary probability values at that symbol,
characterized in that the processor is arranged to operate in two phases consisting of:
a first phase in which the primary probability values are derived for a first sequence of said symbols, and the secondary probability values are derived for a second sequence of said symbols; and
a second phase following the first phase in which in parallel for the two sequences:
(i) the secondary probability values for the first sequence are derived, and used with the primary probability values for the first sequence to derive the third values for the first sequence, and
(ii) the primary probability values for the second sequence are derived, and used with the secondary probability values for the second sequence to derive the third values for the second sequence.

10. A turbo decoder comprising at least one MAP decoder according to claim 9.
